(19) United States
(12) Patent Application Publication
(10) Pub. No.: US 2026/0011655 A1
(43) Pub. Date: Jan. 8, 2026

(54) SiC SEMICONDUCTOR DEVICE AND METHOD OF MANUFACTURING THE SiC SEMICONDUCTOR DEVICE

(71) Applicant: MITSUBOSHI DIAMOND INDUSTRIAL CO., LTD., Settsu city, Osaka (JP)

(72) Inventors: Maki TANAKA, Settsu city (JP); Mitsuru KITAICHI, Settsu City (JP)

(21) Appl. No.: 18/873,364

(22) PCT Filed: Jun. 9, 2023
(86) PCT No.: PCT/JP2023/021511

§ 371 Date: Sep. 30, 2025

(30) Foreign Application Priority Data
Jun. 17, 2022 (JP) 2022-098227

(51) Int. Cl. H01L 23/544; H01L 21/78; H10D 62/832

(52) U.S. Cl. CPC H01L 23/544; H01L 21/78; H01L 2223/5446; H10D 62/8325

(57) ABSTRACT

Provided are an SiC-semiconductor device (1) having properties capable of maximizing the device strength when cut from an SiC-semiconductor wafer (11) by SnB, and a method of manufacturing the SiC-semiconductor device.

The SiC-semiconductor device is produced by, after forming scribe lines (L) in the wafer (11) with a scribing tool, dividing the wafer with external-force application along the lines (L). Created in a sidewall surface of the device (1) is a longitudinal stripe (TL) extending continuously to C surface from a predetermined depth in the sidewall surface exclusive of plastically-deformable region of Si surface and vertical-cracking region formed immediately below the plastically deformable region. The stripe (TL) fulfills the condition of being rectilinearly-shaped or the condition where exterior angle θ formed by intersection of a longitudinal stripe (TL) extending upward from the C (lower) surface with a deflected stripe (KL) resulting from first-time deflection of the stripe (TL) falls within 10°.

### TECHNICAL FIELD

The present invention relates to an SiC (silicon carbide) semiconductor device and a method of manufacturing the SiC semiconductor device.

### BACKGROUND ART

A manufacturing process of a semiconductor device commonly comprises a step of producing a semiconductor wafer, a step of forming a plurality of semiconductor elements (semiconductor electronic circuitries) on the semiconductor wafer, a step of dividing the semiconductor wafer having formed on it the semiconductor elements to obtain semiconductor chips (semiconductor devices), and a step of manufacturing semiconductor devices by using the semiconductor chips.

Examples of the manner of dividing (cutting and segmenting) the semiconductor wafer include blade dicing, known as one of the most typical methods, and also the technique disclosed in Patent Literature 1.

Patent Literature 1 discloses Scribing and Breaking (which may be referred to simply as SnB) technique involving a step of forming scribe lines in a metal film-coated first main surface of a substrate and then segmenting the metal film while causing vertical cracking to propagate at intended segmenting positions through the interior of the substrate, and a step of segmenting the metal film-bearing substrate at the intended segmenting positions by bringing a breaking bar into contact with the substrate from a metal film-free second main surface side.

### PRIOR ART REFERENCE

### Citation List

Patent Literature 1: Re-publication of PCT International Publication No. 2019-082724

### SUMMARY OF INVENTION

### Technical Problem

An SiC semiconductor wafer has an Si surface and a C surface. Customarily the Si surface serves as a mounting surface where a backside electrode is to be mounted, and the C surface located opposite the Si surface serves as a non-mounting surface. The SnB technique may be used to cut out an SiC semiconductor device (SiC semiconductor chip) from the SiC semiconductor wafer. With this technique, either the Si surface or the C surface may be scribed for wafer segmentation. The selection of a surface to be subjected to scribing may be predicated on the structure or manufacturing process of semiconductor chips. According to the described Patent Literature 1, the wafer is scribed at the Si surface, and then broken at the C-surface side, thereby producing SiC semiconductor devices.

Various characteristics and performance capabilities are demanded in the SiC semiconductor device obtained from the SiC semiconductor wafer. With especial regard to residual stress conditions, solder wettability, etc. in the SiC semiconductor device, the applicants are pursuing diligent study and research through inspection, verification, and evaluation.

Meanwhile, no evaluation has been made to date on the condition of the plane of section (sidewall surface) of the SiC semiconductor device, and also on the strength of the SiC semiconductor device in itself. The SiC semiconductor device used for a power semiconductor device or other similar devices may suffer damage due to, for example, generation of heat or stress loading during its operation. This issue of concern arouses a desire for even greater reliability in device strength. Unfortunately, SnB conditions and SiC-semiconductor device properties (conditions of the plane of chip section) best suited to attaining increased strength of the SiC semiconductor device have remained unclear.

In response to the above issue, it is an object of the present invention to provide an SiC semiconductor device having properties that allow the SiC semiconductor device to exhibit a maximum possible strength when cut out of an SiC semiconductor wafer by SnB (Scribing and Breaking) technique, and also to provide a method of manufacturing the SiC semiconductor device.

### Solution to Problem

To achieve the above object, the present invention adopts the following technical means.

An SiC semiconductor device according to an aspect of the present invention is produced by, after forming scribe lines in an SiC semiconductor wafer with a scribing tool, dividing the SiC semiconductor wafer with application of external force along the scribe lines. In a sidewall surface of the SiC semiconductor device, a longitudinal stripe appears so as to extend continuously to a C surface from a predetermined depth in the sidewall surface exclusive of a plastically deformable region of an Si surface and a vertical cracking region formed immediately below the plastically deformable region. The longitudinal stripe fulfills a condition (1) of having a rectilinear shape or a condition (2) where, assuming that the C surface is a lower surface, an exterior angle formed by the intersection of a longitudinal stripe extending upward from the C surface with a deflected stripe resulting from first-time deflection of the longitudinal stripe falls within 10 degrees.

A method of manufacturing an SiC semiconductor device according to an aspect of the present invention comprises forming scribe lines in an SiC semiconductor wafer with a scribing tool, and subsequently dividing the SiC semiconductor wafer with application of external force along the scribe lines. The manufacturing method allows an SiC semiconductor device to be formed so that, in a sidewall surface of the SiC semiconductor device, a longitudinal stripe appears so as to extend continuously to a C surface from a predetermined depth in the sidewall surface exclusive of a plastically deformable region of an Si surface and a vertical cracking region formed immediately below the plastically deformable region, and, the longitudinal stripe fulfills a condition (1) of having a rectilinear shape, or a condition (2) where, assuming that the C surface is a lower surface, an exterior angle formed by the intersection of a longitudinal stripe extending upward from the C surface with a deflected stripe resulting from first-time deflection of the longitudinal stripe falls within 10 degrees.

### Advantageous Effects of Invention

The present invention ensures stable segmentation in the process dividing the SiC semiconductor wafer, reduces the occurrence of problem in a breaking step, and allows the manufactured SiC semiconductor device to have a maximum possible strength.

### BRIEF DESCRIPTION OF THE DRAWINGS

FIG. 1 Schematic views of sidewall surfaces of an SiC semiconductor device.

FIG. 2 Photographs of the sidewall surfaces of the SiC semiconductor device.

FIG. 3 Photographs of sidewall surfaces of SiC semiconductor device segments produced under different conditions.

FIG. 4 A view illustrating a way of conducting a strength test on the SiC semiconductor device and a listing of test conditions.

FIG. 5 A view illustrating an example of the result of a strength test conducted on the SiC semiconductor device.

FIG. 6 A schematic view of an example of an SiC semiconductor wafer from which the SiC semiconductor device embodying the principles of the present invention can be obtained.

### DESCRIPTION OF EMBODIMENTS

An SiC semiconductor device according to an embodiment of the present invention will now be described with reference to the drawings. The following embodiment is given by way of example of carrying the invention into practice, and hence is not intended to be limiting of the structural features of the invention.

The present embodiment will be described with respect to a case where a 4H (Hexagonal)-SiC single crystal is used as a hexagonal SiC single crystal. An SiC semiconductor device 1 obtained pursuant to the invention is suitably used for SiC power semiconductor devices, SiC radio-frequency (RF) devices, compound semiconductor devices, and other similar devices.

An SiC semiconductor wafer 11 will be described first. The SiC semiconductor wafer 11 may be referred to simply as a “wafer 11”, and also the SiC semiconductor device 1 may be referred to simply as a “chip 1”.

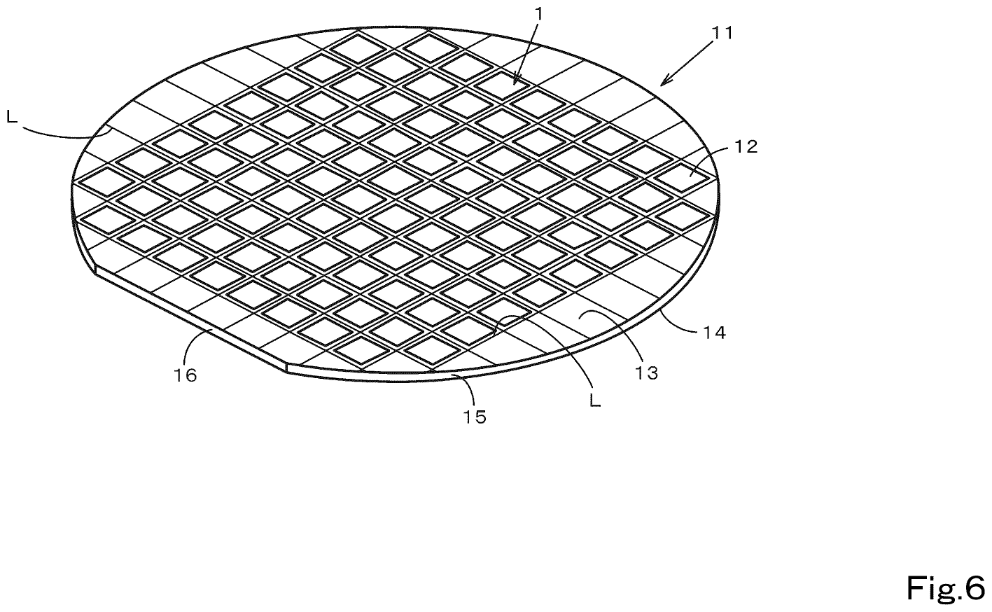

The wafer 11 is schematically shown in FIG. 6. The wafer 11 is a base material used to produce the chip 1 embodying the principles of the invention. In the present embodiment, the wafer 11 includes a semiconductor layer containing a 4H-SiC single crystal.

The wafer 11 is disk-shaped, and has a first main surface 13 on Si side (corresponding to Si surface), a second main surface 14 on C side (corresponding to C surface), and a wafer side wall 15 that connects the first main surface 13 with the second main surface 14. The first main surface 13 forms a plurality of element-forming regions 12 corresponding one-to-one to a plurality of chips 1. The wafer side wall 15 is formed with a cut-out part 16. The cut-out part is called an orientation flat (OF), which serves as a mark indicating the crystal orientation of the SiC single crystal. For example, one or two orientation flats 16 are provided. The wafer 11 is segmented, or divided so as to obtain a plurality of chips 1. For example, each chip 1 measures about 5 mm by 5 mm, and has a thickness of about 1 mm or less. The chip 1 includes an SiC semiconductor layer.

In the present embodiment, the chips 1 are cut out of the wafer 11 by SnB (Scribing and Breaking) technique.

Specifically, the chips 1 are produced by, after forming scribe lines L in the Si surface of the wafer 11 with a scribing tool, dividing the wafer 11 with application of external force along the scribe lines L. Moreover, as a striking feature of the present embodiment, in a sidewall surface of the chip 1, a longitudinal stripe TL appears so as to extend continuously to the C surface from a predetermined depth in the sidewall surface exclusive of a plastically deformable region of the Si surface and a vertical cracking region formed immediately below the plastically deformable region, and, the longitudinal stripe TL fulfills a condition (1) of having a rectilinear shape or a condition (2) where, assuming that the C surface is a lower surface, an exterior angle θ formed by the intersection of a longitudinal stripe TL extending upward from the C surface with a bent, or deflected stripe KL resulting from first-time bending, or deflection of the longitudinal stripe falls within 10 degrees. The condition (2) may be restated as follows. In the presence of the longitudinal stripe TL extending upward from the C surface and the deflected stripe KL resulting from first-time deflection of the longitudinal stripe TL, the smaller one of angles formed by the intersection of the longitudinal stripe TL with the deflected stripe KL is defined as an exterior angle θ or a crossing angle θ in this description. The exterior angle θ (absolute value) falls within 10 degrees.

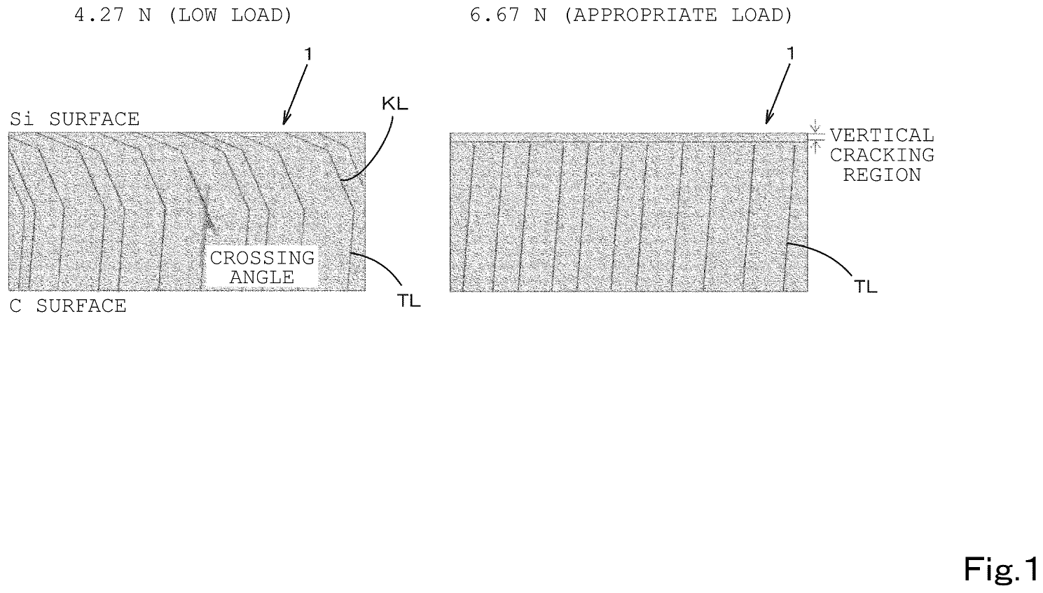

FIG. 1 schematically shows sidewall surfaces of the chip 1.

As shown in the right-hand drawing of FIG. 1, in a sidewall surface of the chip 1, a longitudinal stripe TL appears so as to extend continuously to the C surface from a predetermined depth in the sidewall surface exclusive of a plastically deformable region of the Si surface and a vertical cracking region formed immediately below the plastically deformable region. In this instance, when it is satisfied that the longitudinal stripe TL has a rectilinear shape, it is possible to ensure stable segmentation in wafer division, to reduce the occurrence of problem in the breaking step, and to allow the manufactured chip 1 to have an increased strength.

Meanwhile, as shown in the left-hand drawing of FIG. 1, in a sidewall surface of the chip 1, a longitudinal stripe TL appears so as to extend continuously to the C surface from a predetermined depth in the sidewall surface exclusive of a plastically deformable region of the Si surface and a vertical cracking region formed immediately below the plastically deformable region (the thickness of these regions is equal to about 3 to 10% of the substrate thickness). In this instance, when the longitudinal stripe TL is such that, assuming that the C surface is a lower surface, an exterior angle θ (crossing angle θ) formed by the intersection of a longitudinal stripe TL extending upward from the C surface with a deflected stripe KL resulting from first-time deflection of the longitudinal stripe TL exceeds 10 degrees, then the manufactured chip 1 has a decreased strength.

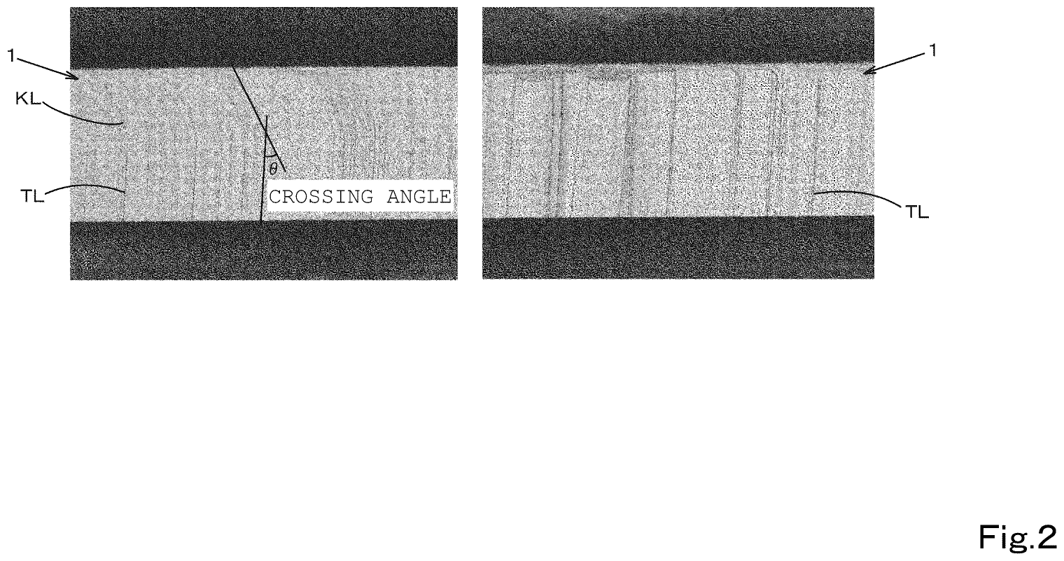

FIG. 2 shows actually photographed images of the sidewall surface of the chip 1 for illustration of sidewall conditions.

In the step of scribing the wafer 11, applying a pressing force of an appropriate loading level to the scribing tool allows the condition shown in the right-hand photograph of FIG. 2 (the longitudinal stripe TL has substantially a rectilinear shape) to be achieved. On the other hand, applying a pressing force of a loading level outside the range of appropriate loading levels (low-level load) to the scribing tool causes the exterior angle θ defined by the intersecting stripes to exceed 10 degrees.

Specifically, for the example shown in the right-hand photograph of FIG. 2, the pressing force applied to the scribing tool in the scribing step stands at an appropriate loading level expressed in equation form as: P=6.67 Newton (symbol: N). In the sidewall surface of the chip 1 obtained by wafer segmentation through a scribing step with application of such an appropriate pressing force, a longitudinal stripe TL appears so as to extend continuously to the C surface from a predetermined depth in the sidewall surface exclusive of a plastically deformable region of the Si surface and a vertical cracking region formed immediately below the plastically deformable region, and, the longitudinal stripe TL has a rectilinear shape. Through diligent study and various experiments, the applicants have found out that a loading level appropriate to the 0.35 mm-thick 4H—SiC wafer 11 falls in the range of about 5 to 8 N.

Meanwhile, the left-hand photograph of FIG. 2 shows the sidewall surface of the chip 1 produced through a scribing step in which a pressing force of a low loading level (=4.27 N) is applied to the scribing tool. It is apparent from the photograph that, in the case of performing scribing with application of such a low load, the resulting longitudinal stripe TL is bent at least twice within one and the same plane, thus creating a longitudinal stripe TL which differs greatly from the longitudinal stripe TL formed in the scribing step with application of the above-described appropriate load (=6.67 N). Furthermore, the vertical cracking region is hardly detectable by observation in the case of performing scribing with application of a low load. Thus, scribing with low-load application makes formation of a vertical crack difficult, and therefore causes lack of stability in the direction of crack propagation in the breaking step, and also causes an undesirable increase of pressing load in the breaking step. Consequently, upon complete segmentation, the ends (the C surfaces) of the substrate segments make contact with one another due to the impact of breaking, leading to the occurrence of chipping. The chipped segment has a decreased strength.

The scribing tool is of a wheel type, which is 2 mm in wheel diameter and 140 degrees in wheel tip angle.

For application of a load exceeding the appropriate load, a chip obtained through a scribing step with application of such a high load may sustain horizontal cracking or chipping at the Si-surface side. To eliminate this problem, it is the rule to avoid scribing with application of an unduly high load which is greater than the appropriate load specified in the present invention. Moreover, according to findings from the study of the applicants, in the case of cutting a bare wafer by the SnB technique, horizontal cracking is less likely to occur and the Si surface has a greater strength (note that the strength of the C surface remains unchanged) in the resulting chip when using a scribing tool having a cutting tip with an obtuse angle than when using a scribing tool having a cutting tip with an acute angle. That is, selection of a proper cutting tip angle permits application of a more appropriate load.

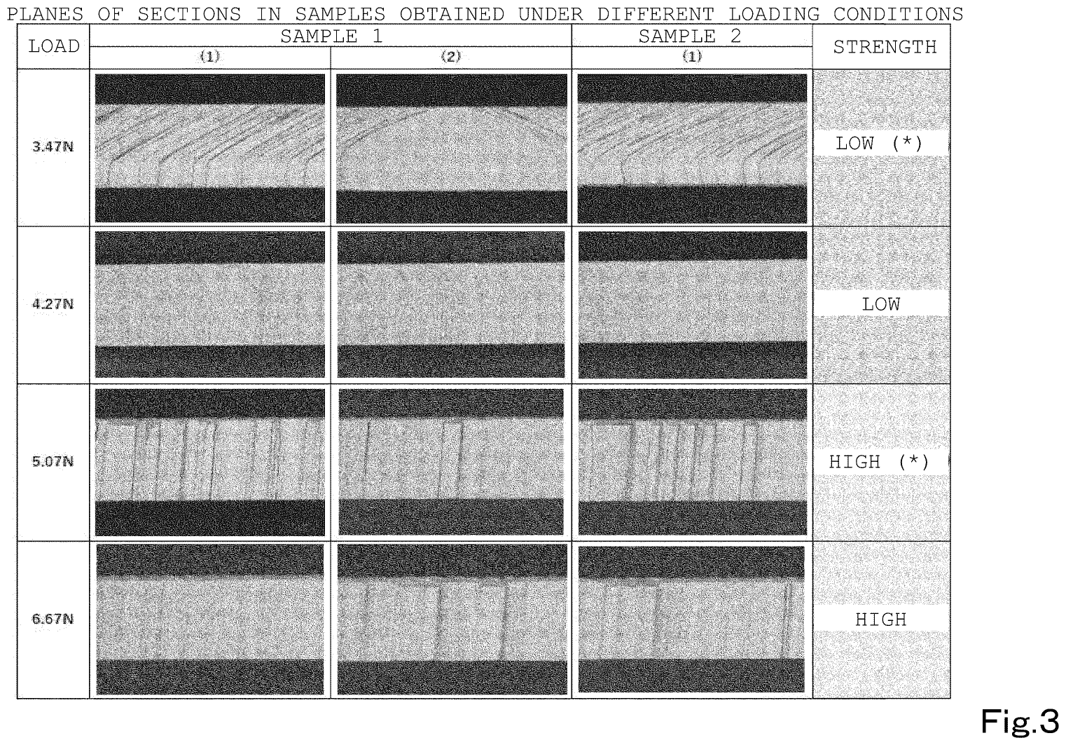

FIG. 3 is a table of enlarged photographs of the sidewall surfaces of various chips 1 produced by segmenting the wafers 11 scribed under different loading conditions.

For evaluation of bending strength as shown in FIG. 3, according to a bend testing method, a bending force is applied to each chip segment 1, and the force required to fracture or break the chip 1 determines the bending strength of the chip 1.

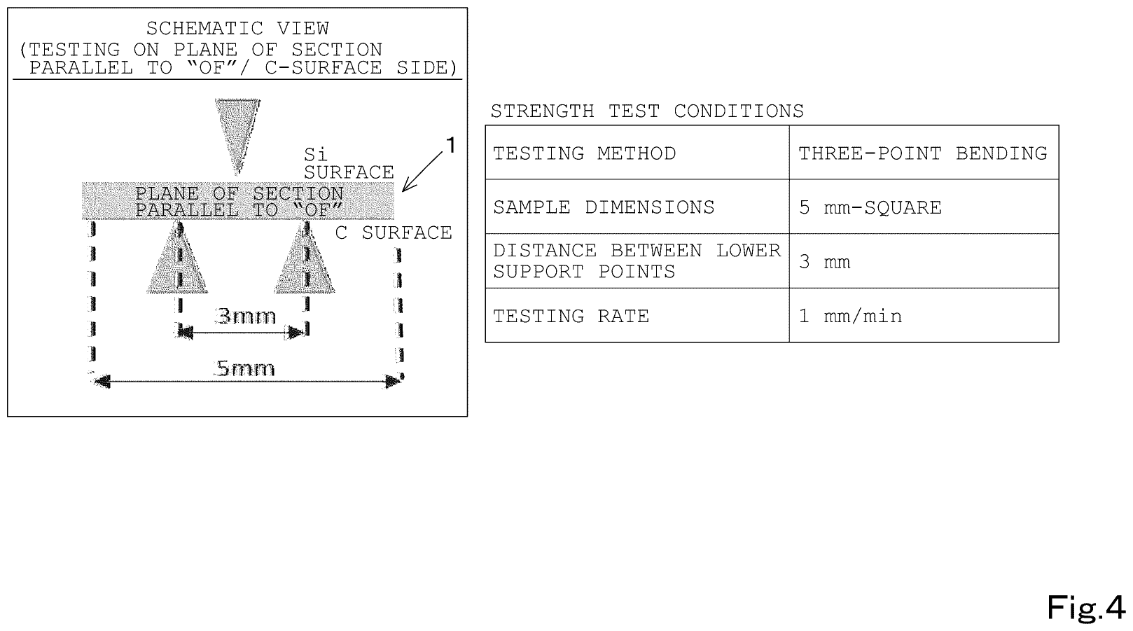

FIG. 4 shows a way of conducting a bending test and test conditions. A chip 1 measuring 5 mm square is used as a test sample. The test sample is supported from below on points spaced 3 mm apart. The central area of the test sample in the supported state is pressed from above at a rate of 1 mm per minute. The pressing force required to fracture or break the test sample determines the bending strength (flexural strength) of the sample. In the test, the test sample is placed so that the plane of sample section parallel to the orientation flat (OF) is perpendicular to a test jig, and, a load is applied to the sample from the Si-surface side.

The higher the flexural strength level, the greater the strength of the chip 1. In this regard, the applicants have found out that the chip 1 of high strength cannot be obtained without application of a pressing force of an appropriate loading level in a scribing step of the SnB process.

With application of a loading force (pressing force) of 5.07 N or 6.67 N, as an appropriate load, to the scribing tool, the resulting chip 1 exhibits a large bending strength value, that is; the chip 1 has a high strength. In a sidewall surface of such a chip 1, a longitudinal stripe TL appears, and this longitudinal stripe TL fulfills a condition (1) of having a rectilinear shape or a condition (2) where, assuming that the C surface is a lower surface, an exterior angle θ formed by the intersection of a longitudinal stripe TL extending upward from the C surface with a deflected stripe KL resulting from first-time deflection of the longitudinal stripe TL falls within 10 degrees.

On the other hand, with application of a low-level load (such as a load of 3.47 N or 4.27 N) to the scribing tool, the resulting chip 1 exhibits a small bending strength value, that is; the chip 1 has a low flexural strength. In a sidewall surface of such a chip 1, a longitudinal stripe TL appears so as to extend arcuately from below upward. This longitudinal stripe TL is such that, assuming that the C surface is a lower surface, an exterior angle θ formed by the intersection of a longitudinal stripe TL extending upward from the C surface with a deflected stripe KL resulting from first-time deflection of the longitudinal stripe TL is greater than 10 degrees.

As seen from the photograph (2) of FIG. 3 associated with the case of applying a load of 3.47 N, for first-time deflection of the longitudinal stripe TL, the stripe TL is not always deflected in a specific direction. The longitudinal stripe TL extending upward from the C surface may be deflected for the first time in either a leftward direction or a rightward direction. Regardless of the deflecting direction of the longitudinal stripe, the chip 1 of high strength (the chip 1 of high flexural strength) can be produced when it is satisfied that an exterior angle θ formed by the intersection of a longitudinal stripe TL extending upward from the C surface with a deflected stripe KL continuous with the longitudinal stripe TL falls within 10 degrees.

In FIG. 3, the test samples rated as being “HIGH (*)” and those rated as being “LOW (*)” in bending strength have not been submitted to strength tests. The strength levels of such samples have been estimated from the results of experimental tests conducted on other corresponding samples (each having a plane of section in which the longitudinal stripe TL appears).

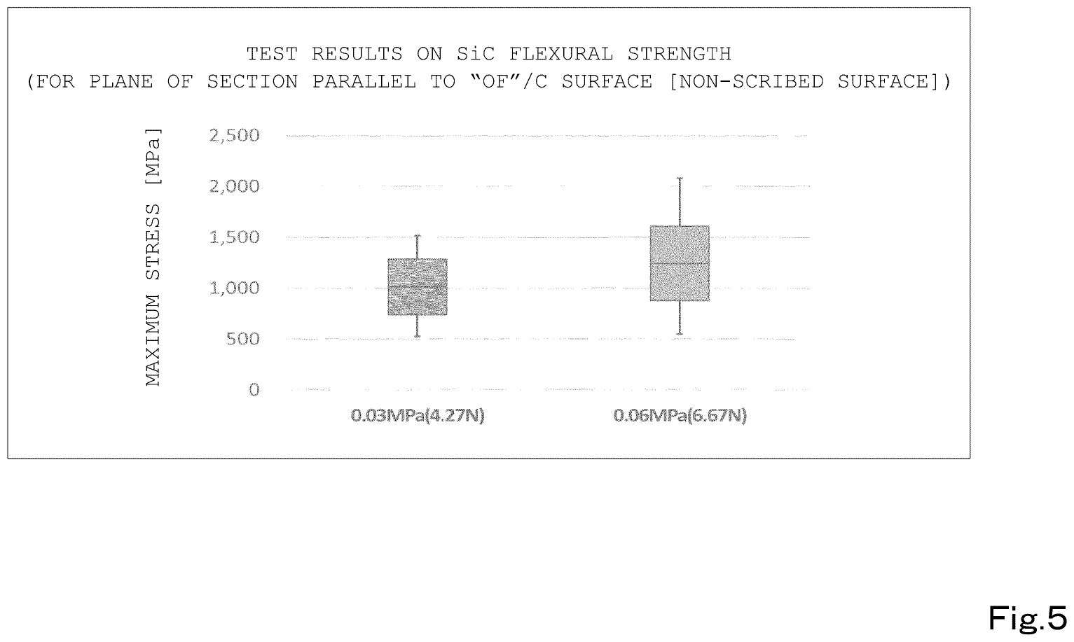

FIG. 5 shows one example of the results of bending-strength evaluation.

The chips 1 produced by segmenting a wafer scribed with application of an appropriate load each have a sidewall surface in which a rectilinear longitudinal stripe TL appears. These chips 1 average 1300 MPa in flexural strength. Included among them is a chip 1 exhibiting a flexural strength of as high as 2000 MPa, which is the greatest value. On the other hand, the chips 1 produced by segmenting a wafer scribed with application of a low load each have a sidewall surface in which an arcuate stripe appears. These chips 1 average 1000 MPa in flexural strength. Even for that one of them which exhibits the highest flexural strength, the flexural strength value is no more than 1500 MPa.

To obtain the described ideal sidewall surfaces, in other words, such sidewall surfaces as are shown in FIGS. 1 and 2, in the present embodiment, the chip 1 is produced in the following manner.

That is, the chip 1 is produced by, after forming scribe lines L in the wafer 11 with a scribing tool (e.g., a scribing wheel), dividing the wafer 11 with application of external force along the scribe lines L.

More specifically, the chip 1 is produced by segmentation of the wafer 11 using a scribing apparatus to form the scribe lines L and a breaking apparatus to divide the wafer 11 with application of external force along the scribe lines L. As shown in FIG. 6, a plurality of chips 1 are produced by, after forming the scribe lines L in the wafer 11, breaking the wafer 11 along the scribe lines L. This process is referred to as SnB (Scribing and Breaking).

For example, the scribe line L may be formed by rolling the scribing wheel along the outer region of the wafer 11, with the cutting tip of the wheel (the edge formed at the periphery of the circular wheel) contacted under pressure with the wafer 11. Besides the scribing wheel, a stationary blade (e.g., a diamond point-type cutter) may be used as the scribing tool.

For a force to press the scribing wheel, adjusting this pressing force to an appropriate loading level allows the sidewall surfaces shown in FIGS. 1 and 2 to be obtained.

The applicants have carried out various experiments on the pressing force, and summarized experimental results in the table shown in FIG. 3. According to findings based on the results, a chip 1 having a sidewall surface which fulfills any one of the following conditions (1) and (2) can be obtained by performing a process step of pressing the scribing wheel against the wafer 11 with a force of 5 to 8 N. The condition (1) is that a longitudinal stripe TL appearing in the sidewall surface has a rectilinear shape. The condition (2) is that, assuming that the C surface is a lower surface, an exterior angle θ formed by the intersection of a longitudinal stripe TL extending upward from the C surface with a deflected stripe KL resulting from first-time deflection of the longitudinal stripe TL falls within 10 degrees.

Besides SnB equipment, which comprises a scribing apparatus and a breaking apparatus, various equipment may be used to obtain the chip 1 from the wafer 11. In the SnB equipment, the scribing apparatus and the breaking apparatus may be either combined into a unitary apparatus or provided as separate and independent apparatuses. Moreover, the range of appropriate loading levels may vary according to substrate thickness or patterns formed at a substrate surface.

As thus far described, when it is satisfied in the chip 1 that a longitudinal stripe TL appearing in the sidewall surface of the chip 1 has a rectilinear shape, or that, in the sidewall surface, assuming that the C surface is a lower surface, an exterior angle θ formed by the intersection of a longitudinal stripe TL extending upward from the C surface with a deflected stripe KL resulting from first-time deflection of the longitudinal stripe TL falls within 10 degrees, then it is possible to ensure stable segmentation in the manufacturing process of the chip, to reduce the occurrence of problem in a breaking step, and to allow the manufactured chip 1 to have a maximum possible strength (a maximum possible three-point bending strength at the C surface, in particular).

It should be understood that the embodiment as disclosed herein is considered in all respects as illustrative only and not restrictive. In particular, for such matters as not explicitly specified in the disclosure of the embodiment, for example, working conditions, operating conditions, and the dimensions, weights, etc. of the constituent components, those that can be readily selected by persons having ordinary skill in the art with reference to TECHNICAL PROBLEM, SOLUTION TO PROBLEM, ADVANTAGEOUS EFFECTS OF INVENTION, etc. disclosed in the present description of the invention.

### REFERENCE SIGNS LIST

1 SiC semiconductor device (Chip)
11 SiC semiconductor wafer
12 Element-forming region
13 First wafer main surface
14 Second wafer main surface
15 Wafer side wall
16 Orientation Flat
L Scribe line
TL Longitudinal stripe
KL Deflected stripe

1. An SiC semiconductor device that is produced by, after forming scribe lines in an SiC semiconductor wafer with a scribing tool, dividing the SiC semiconductor wafer with application of external force along the scribe lines,
the SiC semiconductor device having a sidewall surface in which a longitudinal stripe appears so as to extend continuously to a C surface from a predetermined depth in the sidewall surface exclusive of a plastically deformable region of an Si surface and a vertical cracking region formed immediately below the plastically deformable region,
the longitudinal stripe fulfilling a condition (1) or a condition (2),
the condition (1) being that the longitudinal stripe has a rectilinear shape,
the condition (2) being that, assuming that the C surface is a lower surface, an exterior angle formed by an intersection of a longitudinal stripe extending upward from the C surface with a deflected stripe resulting from first-time deflection of the longitudinal stripe falls within 10 degrees.

2. A method of manufacturing an SiC semiconductor device, comprising:
forming scribe lines in an SiC semiconductor wafer with a scribing tool; and
subsequently dividing the SiC semiconductor wafer with application of external force along the scribe lines,
the manufacturing method allowing an SiC semiconductor device to be formed so that, in a sidewall surface of the SiC semiconductor device, a longitudinal stripe appears so as to extend continuously to a C surface from a predetermined depth in the sidewall surface exclusive of a plastically deformable region of an Si surface and a vertical cracking region formed immediately below the plastically deformable region,
the longitudinal stripe fulfilling a condition (1) or a condition (2),
the condition (1) being that the longitudinal stripe has a rectilinear shape,
the condition (2) being that, assuming that the C surface is a lower surface, an exterior angle formed by an intersection of a longitudinal stripe extending upward from the C surface with a deflected stripe resulting from first-time deflection of the longitudinal stripe falls within 10 degrees.
